(19) United States
(12) Patent Application Publication
(10) Pub. No.: US 2026/0016228 A1
(43) Pub. Date: Jan. 15, 2026

(54) HIGH-PRESSURE ANNEALING DEVICE HAVING FUNCTION OF PREVENTING SCATTERING OF PARTICLES

(71) Applicant: YEST Co., Ltd., Pyeongtaek-si (KR)

(72) Inventors: Young Joon HAM, Pyeongtaek-si (KR); Jeong Eui KIM, Incheon (KR); Yong Hwan KWON, Yongin-si (KR); Jin Seok LEE, Pyeongtaek-si (KR); Byung Wook HWANG, Anseong-si (KR); Yeon Min MO, Pyeongtaek-si (KR); Eun Chan LEE, Yongin-si (KR); Ryun Hwi KIM, Pyeongtaek-si (KR)

(73) Assignee: YEST Co., Ltd., Pyeongtaek-si (KR)

(21) Appl. No.: 19/256,106

(22) Filed: Jun. 30, 2025

(30) Foreign Application Priority Data
Jul. 11, 2024 (KR) 10-2024-0091859

(51) Int. Cl. F27B 17/00; C23C 14/48; C23C 14/58; H01L 21/67

(52) U.S. Cl. CPC F27B 17/0025; C23C 14/5806; C23C 14/48; F27B 2017/0091; H01L 21/67109

(57) ABSTRACT

Disclosed is a high-pressure annealing device including an internal chamber configured to provide an internal space, an external chamber configured to accommodate the internal chamber therein, a heating module configured to perform heat treatment and disposed in an external space provided between the internal chamber and the external chamber, and a shielding element configured to seal the lower portion of the external space, thereby preventing dispersion of particles generated from the heating module and preventing contamination of a substrate (a semiconductor wafer) due to the particles.

### CROSS-REFERENCE TO THE RELATED APPLICATION

The present application claims priority to and the benefit of Korean Patent Application No. 10-2024-0091859, filed on Jul. 11, 2024, in the Korean Intellectual Property Office, the entire disclosure of which is incorporated herein by reference.

### BACKGROUND

### 1. Field

An embodiment of the present disclosure relates to a device configured to perform an annealing process on a substrate.

### 2. Description of the Related Art

When an ion implantation process is performed to manufacture a semiconductor device and the like, damage to a substrate such as a semiconductor wafer may occur. In this case, an annealing process may be performed to recover the structural properties of a substrate from such damage to the substrate.

Generally, an annealing device used to perform the annealing process may include a chamber configured to provides a substrate processing space in which heat treatment is performed on a substrate, and a heating module configured to raise, through a heating process, the temperature of the substrate processing space provided in the chamber to a temperature in the range required for the annealing process. The chamber may be formed to have a structure in which a lower portion of the chamber is open, and the open lower portion may be opened and closed by a door. The heating module may include a heater and may be configured to surround the chamber. When the door is opened, the substrate may be introduced into or discharged from the substrate processing space through the open lower portion of the chamber.

The annealing device configured as described above may provide, through the heating module, high heat during the annealing process, so that the surface of the heating module may be peeled off or removed due to thermal damage thereto. In addition, friction may occur between parts of the heating module due to thermal expansion of the heating module. In this case, a large number of particles may be generated due to such peeling, removal, and friction. The generated particles may be dispersed by scattering and may contaminate the surroundings.

Particularly, during the process of introducing or discharging the substrate into or from the substrate processing space, particles may be attached to the surface of the substrate and may contaminate the substrate, leading to deterioration in yield.

### RELATED ART DOCUMENT

### Patent Document

(Patent Document 1) Korean Patent Laid-Open Publication No. 10-2006-0042705 (filed on May 15, 2006)
(Patent Document 2) Korean Patent Laid-Open Publication No. 10-2014-0039987 (filed on Apr. 2, 2014)
(Patent Document 3) Korean Patent Laid-Open Publication No. 10-2015-0086831 (filed on Jul. 29, 2015)

### SUMMARY

Therefore, the present disclosure has been made in view of the above problems, and it is an object of the present disclosure to provide a high-pressure annealing device configured to prevent contamination caused by particles from a heating module.

It is another object of the present disclosure to provide a high-pressure annealing device configured not only to prevent contamination caused by particles, but also to stably support a chamber.

The objects of the present disclosure are not limited to the above-mentioned objects, and other technical objects not mentioned herein will be clearly understood by those skilled in the art to which the present disclosure pertains from the detailed description of the embodiments.

In accordance with an aspect of the present disclosure, the above and other aspects can be accomplished by the provision of a high-pressure annealing device including an internal chamber configured to provide an internal space to perform heat treatment on a substrate (such as a semiconductor wafer), the internal chamber having an open lower portion, an external chamber configured to accommodate the internal chamber therein, the external chamber having an open lower portion, a heating module configured to heat the internal chamber and disposed in an external space provided between the internal chamber and the external chamber spaced apart from each other, a chamber door configured to open or close, through an upward-and-downward movement operation, at least one of the open lower portion of the internal chamber or the open lower portion of the external chamber facing the internal chamber, the chamber door being configured to move to a closed position during the upward movement operation and to move to an open position during the downward movement operation, a substrate supporting unit (a substrate holder) mounted on the upper portion of the chamber door, the substrate supporting unit entering or exiting (being introduced into or discharged from) the internal space in response to the upward-and-downward movement operation of the chamber door through the open lower portion of the internal chamber, and a shielding element (a shielding cover) located between the internal chamber and the external chamber and configured to seal an open lower portion of the external space.

In the high-pressure annealing device according to the embodiment of the present disclosure, a first gas, which is a reaction gas, may be supplied to the internal space at a first pressure (higher pressure than atmospheric pressure), and a second gas, which is a protective gas, may be supplied to the external space at a second pressure (same pressure as the first pressure, or slightly higher or lower pressure than the first pressure) predetermined in relation to the first pressure.

The internal chamber may be formed of quartz, which is a non-metallic material. The external chamber may be formed of a metallic material. The shielding element may be configured to support, in a contact manner, a lower end portion of the internal chamber which is formed of quartz in a state of being coupled to a lower end portion of the external chamber which is formed of a metallic material, thereby stably positioning the internal chamber in the internal space provided in the external chamber.

The shielding element may include an upper cover module having a ring-shaped structure, the upper cover module being configured to seal the lower portion of the external space in a state in which a peripheral portion of the upper cover module is coupled to a lower end portion of the external chamber and a central portion thereof supports a lower end portion of the internal chamber, a spacer having a ring-shaped structure, the spacer being configured to support the upper cover module from below, and a lower cover module having a ring-shaped structure, the lower cover module being disposed below the upper cover module and being configured to seal the lower portion of the external space in a state in which a peripheral portion of the lower cover module is coupled to the lower end portion of the external chamber and a central portion thereof supports the spacer.

The internal chamber may have a flange provided at the lower end portion of the internal chamber. The upper cover module may support the flange of the internal chamber.

The upper cover module may include an upper cover including a peripheral ring portion coupled to the lower end portion of the external chamber and a central ring portion formed to have a supporting upper surface adapted to support the flange of the internal chamber from below, and a pressing ring coupled to the upper cover from above the upper cover, the pressing ring having a pressing lower surface adapted to press the flange.

The heating module may have a flange provided at a lower end portion thereof, the flange being coupled to the lower end portion of the external chamber. The peripheral ring portion of the upper cover may be coupled to the lower end portion of the heating module such that the upper cover is coupled to the lower end portion of the external chamber with the heating module interposed therebetween.

The heating module may have a ring jaw disposed above the pressing ring. The upper cover module may further include an elastic member. The elastic member may be interposed between the ring jaw and the pressing ring in a vertically compressed state.

The upper cover module may further include a buffer pad interposed between the pressing lower surface of the pressing ring and the flange of the internal chamber.

In accordance with another aspect of the present disclosure, there is provided a high-pressure annealing device including an internal chamber configured to provide an internal space to perform heat treatment on a substrate, the internal chamber having an open lower portion, an external chamber configured to accommodate the internal chamber therein, the external chamber having an open lower portion, a heating module configured to heat the internal chamber and disposed in an external space provided between the internal chamber and the external chamber, a chamber door configured to open or close, through an upward-and-downward movement operation, at least one of the lower portion of the internal chamber or the lower portion of the external chamber, a substrate holder provided on the chamber door, the substrate holder entering and exiting the internal space in response to the upward-and-downward movement operation of the chamber door, and a shielding element located between the internal chamber and the external chamber and configured to seal a lower portion of the external space. The shielding element includes an upper cover and a lower cover disposed below the upper cover, and the shielding element is configured to double-seal the lower portion of the external space using the upper cover and the lower cover.

The above-described technical solutions will be more specifically and clearly described through embodiments, drawings, and the like. In addition, various technical solutions other than the technical solutions described below may be additionally implemented.

### BRIEF DESCRIPTION OF THE DRAWINGS

The accompanying drawings, which are incorporated in this specification, illustrate exemplary embodiments and serve to further illustrate the technical ideas of the disclosure in conjunction with detailed the description of exemplary embodiments that follows, and the disclosure is not to be construed as limited to what is shown in such drawings. In the drawings:

FIG. 1 is a cross-sectional view of a high-pressure annealing device according to an embodiment of the present disclosure; and

FIGS. 2 to 9 are views each showing a configuration, a coupling relationship, and the like of a shielding element applied to the high-pressure annealing device according to the embodiment of the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

In describing the embodiments disclosed herein, when it is determined that a detailed description of a related publicly known function or configuration may obscure the gist of the present disclosure, the detailed description thereof will be omitted, and the same or similar components will be denoted by the same reference numerals throughout the drawings.

Since at least some of the terms used in the specification are defined in consideration of the functions in the present disclosure, the terms may vary depending on a user, an operator's intention, a custom, and the like. Therefore, the terms should be interpreted based on the contents throughout the specification. Furthermore, throughout the specification, when a component is referred to as “comprising”, “including”, or “having” a certain component, the component should not be understood as excluding other components, unless explicitly described to the contrary, and the component may further include other components. In the present disclosure, when a component is referred to as being “connected”, “coupled”, or “joined” to another component, the component and the other component may be “directly connected”, “directly coupled”, or “directly joined” to each other, or may be “indirectly connected”, “indirectly coupled”, or “indirectly joined” to each other with one or more intervening components interposed therebetween.

Meanwhile, the size or shape of components, the thickness of lines, and the like in the drawings may be somewhat exaggerated for convenience of understanding.

An embodiment of the present disclosure relates to a high-pressure annealing device capable of performing an annealing process and the like on a substrate such as a semiconductor wafer under high-pressure conditions for the manufacture of a semiconductor device and the like, preventing contamination of the substrate due to particles from a heating module, and simply and safely fixing the position of an internal chamber in place.

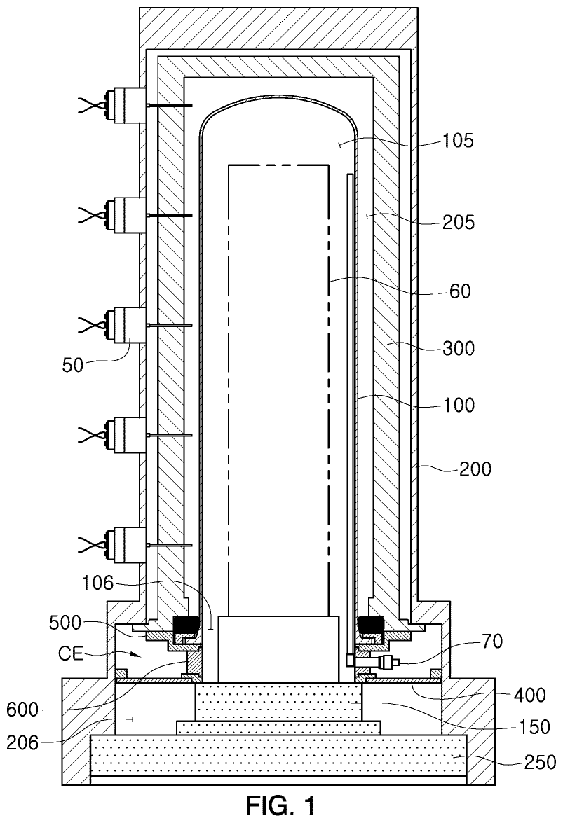

A high-pressure annealing device according to an embodiment of the present disclosure is shown in FIG. 1. FIG. 1 is a cross-sectional view schematically showing the main parts of the high-pressure annealing device according to the embodiment of the present disclosure.

As shown in FIG. 1, the high-pressure annealing device according to the embodiment of the present disclosure may include an internal chamber 100 configured to provide an internal space 105 (a substrate processing space) capable of being blocked from the outside for heat treatment of a substrate, an external chamber 200 configured to accommodate the internal chamber 100 therein, and a heating module 300 disposed in an external space 205 (a protection space) provided between the internal chamber 100 and the external chamber 200 spaced apart from each other.

In addition, although not shown in the drawings, the high-pressure annealing device according to the embodiment of the present disclosure may further include a first gas supply/exhaust unit and a second gas supply/exhaust unit. The first gas supply/exhaust unit may supply a first gas to the internal space 105 and may discharge the supplied first gas from the internal space 105. The first gas may be a reaction gas. The second gas supply/exhaust unit may supply a second gas to the external space 205 and may discharge the supplied second gas from the external space 205. The second gas may be a protective gas.

In addition, the high-pressure annealing device according to the embodiment of the present disclosure may further include at least one temperature sensor assembly 50 configured to detect the temperature of the heating module 300, a pressure measuring device (not shown) configured to detect the pressure of the internal space 105 and the pressure of the external space 205, and a control unit (not shown) configured to control the heating module 300 based on the detected temperature input from the temperature sensor assembly 50 and to control the first gas supply/exhaust unit and the second gas supply/exhaust unit based on the detected pressure input from the pressure measuring device.

In the high-pressure annealing device according to the embodiment of the present disclosure configured as described above, when an annealing process is performed, the substrate is accommodated in the internal space 105, and the internal chamber 100 is heated by the heating module 300 such that the internal space 105 has a high-temperature atmosphere for heat treatment of the substrate. Additionally, the temperature of the internal space 105 may be maintained at a set temperature required for the annealing process through a control operation of the control unit on the heating module 300.

In addition, in the high-pressure annealing device according to the embodiment of the present disclosure, when the annealing process is performed, the first gas (reaction gas) may be supplied to the internal space 105 by the first gas supply/exhaust unit, and the second gas (protective gas) may be supplied to the external space 205 by the second gas supply/exhaust unit. The first gas (reaction gas) supplied to the internal space 105 may be raised to a reaction temperature by the heating operation of the heating module 300, and for example, may improve interface characteristics of the substrate. While the annealing process is performed, the pressure of the internal space 105 may be adjusted to a first pressure within a range required for the annealing process through a control operation of the control unit on the first gas supply/exhaust unit, and the pressure of the external space 205 may be adjusted to a second pressure within a range corresponding to the first pressure through a control operation of the control unit on the second gas supply/exhaust unit. The first pressure (the pressure of the internal space 105) may be higher than atmospheric pressure. For example, the first pressure may be several to several hundred atmospheres. The second pressure (the pressure of the external space 205) provided by the second gas (protective gas) may be the same pressure as the first pressure. Alternatively, the second pressure may be slightly higher or lower than the first pressure. Through the above-described pressure control, the internal chamber 100 and the like may be prevented from being damaged or broken due to a pressure difference between the internal space 105 and the external space 205.

The internal chamber 100 may be formed of a non-metallic material. If the internal chamber 100 is formed of a non-metallic material, metal contamination of the substrate, which may occur under a high temperature and a high pressure environment, may be prevented. The material of the internal chamber 100 may be quartz. The substrate may be introduced into the internal space 105 or may be discharged from the internal space 105 in a state of being supported by a substrate holder 60. The substrate holder 60 serving as a substrate supporting unit may be configured to support a plurality of substrates. For example, the substrate holder 60 may be a wafer boat that supports a plurality of substrates in a vertically stacked state.

The first gas supplied to the internal space 105 at the first pressure may be selected from various reaction gases for heat treatment, such as hydrogen, deuterium, oxygen, ammonia, and chlorine.

The external chamber 200 may be provided on the outer side of the internal chamber 100 and may be configured to accommodate the internal chamber 100 therein. Further, the external space 205 may be provided between the internal chamber 100 and the external chamber 200. The external chamber 200 may be provided to have higher strength than the internal chamber 100. The external chamber 200 may be formed of a metallic material and may safely protect the brittle internal chamber 100 from the outside.

The second gas (protective gas) supplied to the external space 205 at the second pressure may be selected from inert gases such as argon and nitrogen.

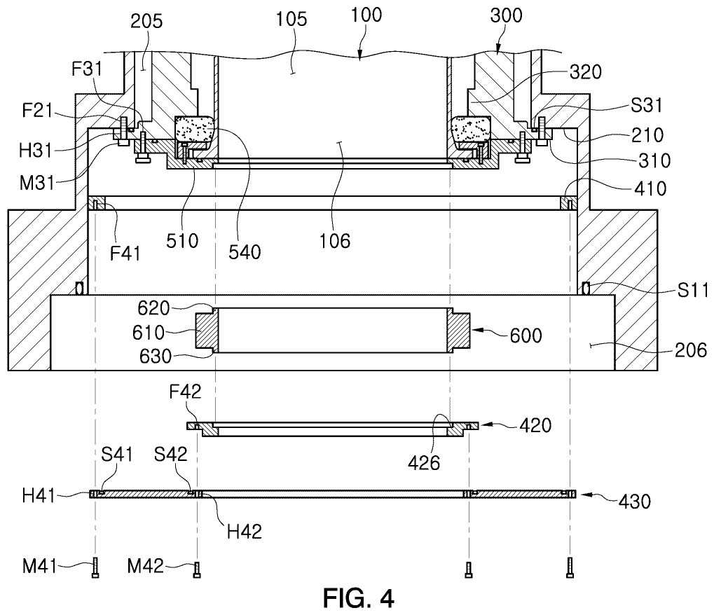

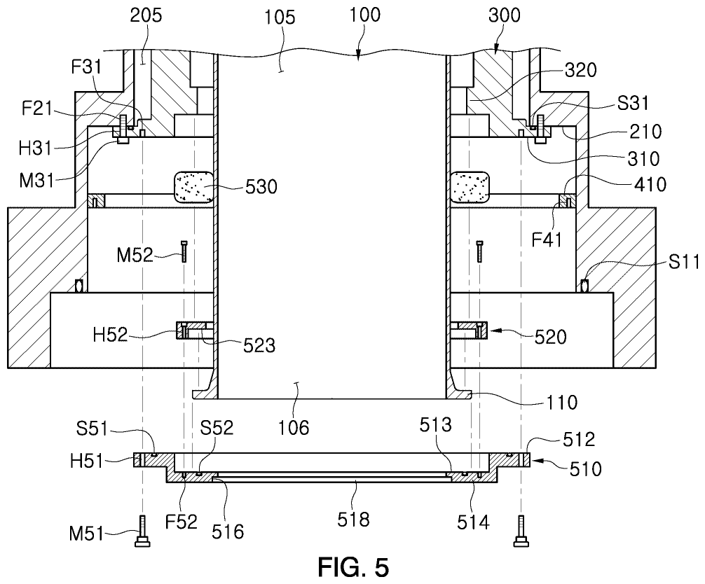

Both the internal chamber 100 and the external chamber 200 may be formed to have a cross section of an approximately circular structure. Each of the internal chamber 100 and the external chamber 200 may have a structure in which a lower portion thereof is open. According to the structure in which the lower portion of each of the internal and external chambers 100 and 200 is open, an internal lower end opening 106 (the open lower portion of the internal chamber 100) at the lower end of the internal chamber 100 may be provided in a shape communicating with the internal space 105 (refer to FIG. 5). Further, an external lower end opening 206 (the open lower portion of the external chamber 200) at the lower end of the external chamber 200 may be provided in a shape communicating with the external space 205 (refer to FIG. 4). The height of the lower end (refer to reference numeral 206) of the external chamber 200 may be lower than the height of the lower end (refer to reference numeral 106) of the internal chamber 100. Therefore, the external lower end opening 206 of the external chamber 200 may be located below the internal lower end opening 106 of the internal chamber 100 and may be disposed to face the internal lower end opening 106. The substrate holder 60 may be introduced into or discharged from the internal space 105 through the internal lower end opening 106 and the external lower end opening 206 which face each other.

In FIG. 1, reference numeral 150 and reference numeral 250 represent an internal door and an external door, respectively, and the internal chamber 100 may have the internal lower end opening 106 opened and closed by the internal door 150, and the external chamber 200 may have the external lower end opening 206 opened and closed by the external door 250. The internal chamber 100 and the external chamber 200 may constitute a chamber. Further, the internal door 150 and the external door 250 may constitute a chamber door. In addition, the chambers 100 and 200 and the internal door 150 and the external door 250 may constitute a chamber unit.

The external door 250 may open and close the external lower end opening 206 through an upward-and-downward movement operation thereof with respect to the external lower end opening 206. Here, when the external lower end opening 206 is closed, the external lower end opening 206 may be sealed using a ring-shaped sealing member (refer to S11 in FIG. 4). The sealing member S11 may be interposed between the external chamber 200 and the external door 250. For example, the sealing member S11 may be provided on the side of the external lower end opening 206 so as to be interposed between the external chamber 200 and the external door 250.

The external door 250 may be accurately moved upwards or downwards by an upward/downward movement driving unit (not shown) such as a lifter. The internal door 150 is provided on the external door 250. Accordingly, when the external door 250 is moved upwards or downwards by power supplied from the upward/downward movement driving unit, the internal door 150 may be moved upwards or downwards in conjunction with upward/downward movement of the external door 250. When the chamber doors 150 and 250 are moved to the closed position by upward movement of the external door 250 such that the external door 250 closes the external lower end opening 206, the internal door 150 may approach the internal lower end opening 106 and may close the internal lower end opening 106. In addition, when the chamber doors 150 and 250 are moved from the closed position to the open position by downward movement of the external door 250 such that the external door 250 opens the external lower end opening 206, the internal door 150 may be spaced apart from the internal lower end opening 106 and may open the internal lower end opening 106.

The substrate holder 60 may be provided on the internal door 150 and may enter and exit the internal space 105 through the upward-and-downward movement operation of the external door 250. Specifically, when the chamber doors 150 and 250 are moved to the closed position by upward movement of the external door 250, the substrate holder 60 may be introduced into the internal space 105 while sequentially passing through the external lower end opening 206 and the internal lower end opening 106. Thereafter, when the chamber doors 150 and 250 are moved from the closed position to the open position by downward movement of the external door 250, the substrate holder 60 may be discharged from the internal space 105 to the outside of the chambers 100 and 200 while passing through the internal lower end opening 106 and the external lower end opening 206. When the substrate holder 60 is discharged, the substrate may be loaded on or unloaded from the substrate holder 60.

The heating module 300 may be formed to have a shape that surrounds the wall and ceiling (that is, the upper portion) of the internal chamber 100. The heating module 300 may be provided to form a part of the external chamber 200 or may be provided separately from the external chamber 200. The heating module 300 may include a heater, and the heater may be provided as a heating wire. The heating module may further include a heater supporting member that supports the heater (heating wire) from the outside. For example, the heater supporting member may be formed of an insulating material.

The heating module 300 may have a plurality of heating zones arranged in the vertical direction. The heater of the heating module 300 may be formed of a plurality of heaters, and at least one heater may be disposed in each of the plurality of heating zones. The temperatures of the plurality of heating zones may be independently adjusted. The temperature sensor assembly 50 may be provided in plural, and each of the temperature sensor assemblies may be disposed at a height corresponding to a corresponding one of the plurality of heating zones so as to detect the temperature of the heating module 300 for each heating zone. The control unit may control the heating module 300 for each heating zone based on the detected temperatures input from the temperature sensor assemblies 50.

Since the heating module 300 is maintained at a high temperature during heat treatment, the heating module 300 may generate particles when the surfaces of the heater (heating wire), the heater supporting member, and the like are peeled off or removed due to thermal damage. Further, particles may be generated by friction between the heater and the heater supporting member formed of an insulating material due to thermal expansion. The particles generated from the heating module 300 within the external space 205 may fall toward the external door 250 disposed below the heating module 300 and may contaminate the external door 250. Additionally, the particles generated as described above may be caught between the external chamber 200 and the external door 250, leading to deterioration in sealing performance therebetween. In particular, during the process in which the substrate holder 60 is inserted into or discharged from the internal space 105, the generated particles may be dispersed to the surroundings by scattering thereof and may be attached to substrates loaded on the substrate holder 60 such that the substrates are contaminated.

In order to solve the problems caused by particles generated from the heating module 300, the high-pressure annealing device according to the embodiment of the present disclosure may further include a shielding element CE located above the external door 250 and configured to seal the lower portion of the external space 205 to prevent particles generated from the heating module 300 from being discharged from the external space 205.

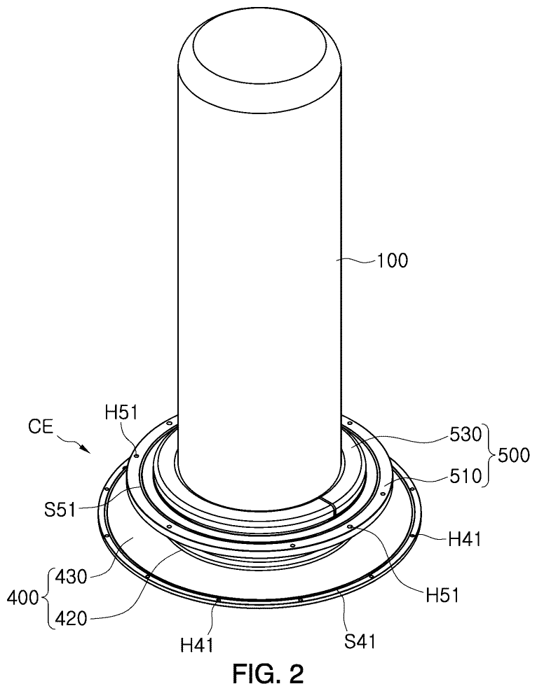

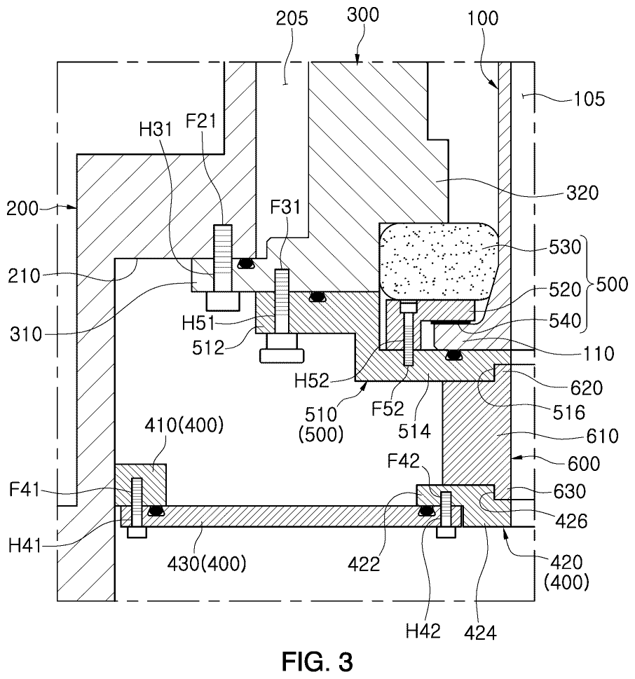

A configuration, a coupling relationship, and the like of the shielding element CE are shown in FIGS. 2 to 9. FIG. 2 is a perspective view of the shielding element CE together with the internal chamber 100. FIG. 3 is a cross-sectional view specifically showing a part of the shielding element CE. FIGS. 4 and 5 are cross-sectional views each showing a state in which the shielding element (CE) and the like are disassembled.

Referring to FIG. 1, the shielding element CE may be formed to have a cover structure capable of sealing the lower portion of the external space 205 provided between the internal chamber 100 and the external chamber 200. Referring to FIG. 3, the shielding element CE may be configured to be coupled to the lower end portion of the external chamber 200 having excellent strength and to support the lower end portion of the brittle internal chamber 100 in a contact manner, thereby more accurately fixing the position of the internal chamber 100. In addition, the shielding element CE may include an upper cover 510 and may further include a lower cover 430 disposed below the upper cover 510, thereby obtaining a configuration in which the lower portion of the external space 205 is more reliably double-sealed by the upper cover 510 and the lower cover 430. The shielding element CE will be described as follows.

Referring to FIGS. 2 to 4, the shielding element CE may include an upper cover module 500 having a ring-shaped structure, configured to seal the lower portion of the external space 205 in a state in which a peripheral portion of the upper cover module 500 is coupled to the lower end portion of the external chamber 200 and a central portion thereof supports the lower end portion of the internal chamber 100, a spacer 600 having a ring-shaped structure, configured to support the upper cover module 500 from below, and a lower cover module 400 having a ring-shaped structure, disposed below the upper cover module 500 and configured to seal the lower portion of the external space 205 in a state in which a peripheral portion of the lower cover module 400 is coupled to the lower end portion of the external chamber 200 and a central portion thereof supports the spacer 600.

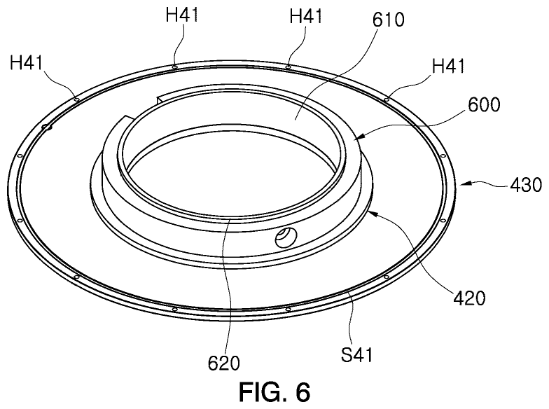

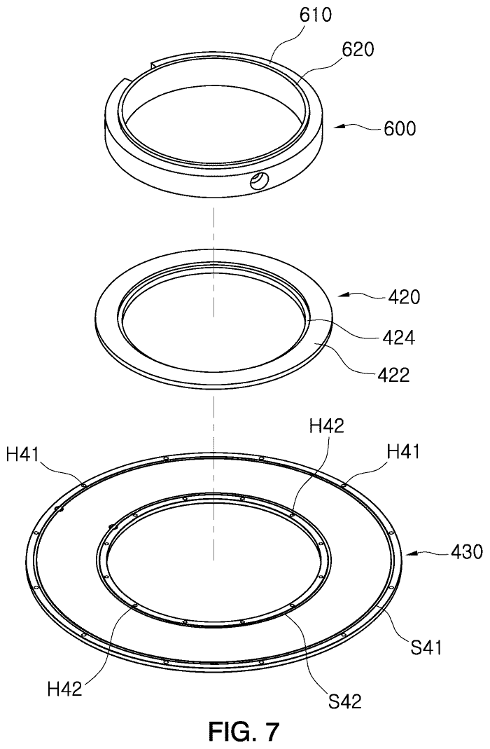

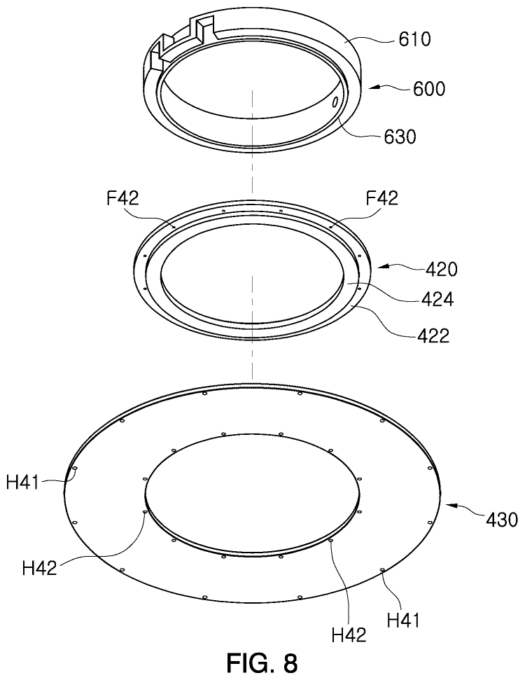

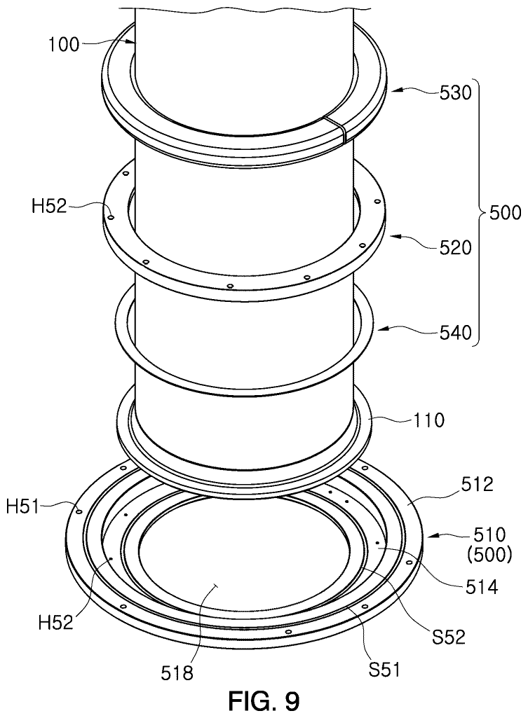

FIG. 6 is a perspective view showing a state in which the lower cover module 400 and the spacer 600 are assembled with each other (coupled to each other). FIGS. 7 and 8 are exploded perspective views of the lower cover module 400 and the spacer 600, which are perspective views viewed from different angles. FIG. 9 is an exploded perspective view of the upper cover module 500 together with the internal chamber 100.

Referring to FIGS. 3, 5, and 9, the internal chamber 100 may have a flange 110 formed to protrude outwards from the lower end thereof and provided along the circumference of the lower end. The upper cover module 500 may be provided to support the flange 110 of the internal chamber 100 in a contact manner.

As shown in FIGS. 2 to 5 and FIG. 9, the upper cover module 500 may include the upper cover 510 having a circular ring structure and a pressing ring 520 having a circular structure. The upper cover 510 may be configured to include a peripheral ring portion 512 reliably coupled to the lower end portion of the external chamber 200, and a central ring portion 514 formed to have a supporting upper surface 513 adapted to support the flange 110 of the internal chamber 100 from below. The pressing ring 520 may be located above the upper cover 510 and may be coupled to the upper cover 510. Further, the pressing ring 520 may be configured to include a pressing lower surface 523 adapted to press the flange 110 of the internal chamber 100.

The central ring portion 514 of the upper cover 510 may be formed to have a central opening 518 having a size and a shape corresponding to those of the internal lower end opening 106 of the internal chamber 100 (refer to FIG. 5). The upper cover 510 and the pressing ring 520 may be coupled to each other by bolts M52. The central ring portion 514 of the upper cover 510 has female screw grooves F52 formed therein and circumferentially arranged with an interval therebetween, and the pressing ring 520 has through-holes H52 formed therein and arranged to correspond to the respective female screw grooves F52 in the central ring portion 514. Here, the bolts M52 configured to couple the upper cover 510 to the pressing ring 520 may be screwed in the respective female screw grooves F52 in the central ring portion 514 through the respective through-holes H52 in the pressing ring 520 (refer to FIGS. 3 and 5). As shown in FIG. 5, one or plural sealing members S52 such as an O-ring may be interposed between the lower surface of the flange 110 constituting the internal chamber 100 and the supporting upper surface 513 of the central ring portion 514 constituting the upper cover 510, thereby maintain airtightness therebetween. The sealing members S52 interposed between the flange 110 of the internal chamber 100 and the central ring portion 514 of the upper cover 510 may be provided on the supporting upper surface 513 of the central ring portion 514 in the circumferential direction, and each of the sealing member S52 may be formed to have a circular ring shape.

Referring to FIGS. 3 to 5, the heating module 300 may have a circular structure flange 310 coupled to the lower end portion of the external chamber 200 and provided at the lower end of the heating module 300. The flange 310 of the heating module 300 may be formed to protrude outwards and may be provided along the circumference of the lower end of the heating module 300. The external chamber 200 may have a ring-shaped step 210 formed to provide the lower surface of the external chamber, which faces the upper surface of the flange 310 of the heating module 300, and provided at the lower end portion of the internal wall of the external chamber 200. The external chamber 200 and the heating module 300 may be coupled to each other by bolts M31. The flange 310 of the heating module 300 may have through-holes H31 formed therein and circumferentially arranged with an interval therebetween, the step 210 of the external chamber 200 may have female screw grooves F21 formed therein and arranged to correspond to the respective through-holes H31 in the heating module 300, and the bolts M31 for coupling of the external chamber 200 to the heating module 300 may be screwed in the respective female screw grooves F21 in the step 210 through the respective through-holes H31 in the heating module 300. A sealing member S31 configured to maintain airtightness may be interposed between the step 210 of the external chamber 200 and the flange 310 of the heating module 300. The sealing members S31 interposed between the step 210 of the external chamber 200 and the flange 310 of the heating module 300 may be arranged in the circumferential direction of the flange 310 of the heating module 300. Each of the sealing members S31 interposed between the step 210 of the external chamber 200 and the flange 310 of the heating module 300 may be formed to have a ring shape.

The upper cover 510 may be coupled to the lower end portion of the external chamber 200 via the heating module 300 by coupling the peripheral ring portion 512 to the lower end portion of the heating module 300. Referring to FIG. 5, the heating module 300 and the upper cover 510 may be coupled to each other by bolts M51. The peripheral ring portion 512 of the upper cover 510 may have through-holes H51 formed therein and circumferentially arranged with an interval therebetween, the heating module 300 may have female screw grooves F31 formed therein and arranged to correspond to the respective through-holes H51 in the peripheral ring portion 512, and the bolts M51 for coupling of the heating module 300 to the upper cover 510 may be screwed in the respective female screw grooves F31 in the heating module 300 through the respective through-holes H51 in the peripheral ring portion 512. A space between the heating module 300 and the upper cover 510 may be maintained in the airtight state by a sealing member S51. The sealing member S51 configured to maintain airtightness between the heating module 300 and the upper cover 510 may be interposed between the lower end portion of the heating module 300 and the peripheral ring portion 512 of the upper cover 510. The sealing members S51 interposed between the heating module 300 and the upper cover 510 may be provided in the circumferential direction of the peripheral ring portion 512. Each of the sealing members S51 interposed between the heating module 300 and the upper cover 510 may be formed to have a ring shape.

The heating module 300 may have a ring jaw 320 disposed above the pressing ring 520. The upper cover module 500 may further include an elastic member 530 (an elastic ring) formed to have a circular ring structure. The elastic member 530 may be interposed between the lower surface of the ring jaw 320 and the upper surface of the pressing ring 520 in a vertically compressed state. When the elastic member 530 is interposed between the lower surface of the ring jaw 320 and the upper surface of the pressing ring 520, and the upper cover 510 is coupled to the heating module 300 by the bolts M51, the elastic member 530 may be compressed in the vertical direction by the upper ring jaw 320 and the lower pressing ring 520 disposed therebelow. The elastic member 530 may be flattened by vertical compression and may be deformed into a shape in which the internal circumferential surface of the elastic member 530 is in close contact with the external circumferential surface of the internal chamber 100. Through the elastic member 530, the pressed state of the pressing ring 520 with respect to the flange 110 of the internal chamber 100 may be stably maintained. Additionally, the elastic member 530 may reliably support the periphery around the entire lower portion of the internal chamber 100.

Referring to FIG. 3, FIG. 9, and the like, the upper cover module 500 may further include a pad 540 having a ring-shaped structure, which is interposed between the pressing lower surface 523 (refer to FIG. 5) of the pressing ring 520 and the upper surface of the flange 110 of the internal chamber 100. The pad 540 is a buffer pad having a shock-absorbing function and the like, and the buffer pad 540 may be configured to have a predetermined elasticity. For example, the buffer pad 540 may be formed of an elastic material such as rubber and so as to have a sealing function along with the shock-absorbing function. The buffer pad 540 configured as described above may absorb stress, impact, and the like that may be applied to the flange 110 of the internal chamber 100 when the flange 110 of the internal chamber 100 is pressed by the pressing ring 520. Accordingly, the buffer pad 54 may prevent damage to the flange 110 of the internal chamber 100 having brittleness. Although not shown in the drawings, a pad substantially identical or similar to the buffer pad 540 may be interposed between the supporting upper surface 513 (refer to FIG. 5) of the central ring portion 514 of the upper cover 510 and the lower surface of the flange 110 of the internal chamber 100.

Referring to FIG. 1, FIG. 4, FIG. 6, and the like, the spacer 600 may be provided as a manifold. A ring-shaped body 610 of the manifold 600 may support a nozzle assembly 70 configured to distribute the first gas to the internal space 105. The first gas supply/exhaust unit may be connected to the nozzle assembly 70 so as to supply the first gas to the internal space 105 through the nozzle assembly 70.

Referring to FIG. 3, FIG. 6 to FIG. 8, and the like, the lower cover module 400 may include an inward flange member 410, a central coupling member 420, and the lower cover 430 between the flange member 410 and the coupling member 420.

The flange member 410 may be provided at the lower end portion of the external chamber 200. The flange member 410 may protrude inwards and may be provided along the internal circumference of the lower end portion of the external chamber 200. For example, the flange member 410 may be formed to be integrated with the external chamber 200 or may be welded to the external chamber 200.

The coupling member 420 may be formed to have a ring structure. The coupling member 420 may be formed to have an opening corresponding to the internal lower end opening 106 of the internal chamber 100. The coupling member 420 may be provided to include a central coupling portion 424 having an opening corresponding to the internal lower end opening 106 of the internal chamber 100 and a peripheral coupling portion 422 formed along the periphery of the central coupling portion 424.

The central coupling portion 424 of the coupling member 420 may have a jaw 426 coupled to a ring-shaped lower protrusion 630 of the manifold 600 serving as a spacer (refer to FIGS. 3 and 4). The manifold 600 may have a ring-shaped upper protrusion 620, and the central ring portion 514 of the upper cover 510 may have a jaw 516 coupled to the upper protrusion 620 of the manifold 600 (refer to FIGS. 3 and 5). Although not shown in the drawings, a sealing member may be interposed between the upper cover 510 and the manifold 600 and between the coupling member 420 and the manifold 600, respectively. The position of the manifold 600 may be fixed by the jaws 426 and 516.

The lower cover 430 may be formed to have a ring structure. The upper surface of the peripheral portion of the lower cover 430 may be coupled to the lower surface of the flange member 410 by bolts M41. Referring to FIGS. 3, 4, 6 to 8, and the like, the lower cover 430 may have through-holes H41 formed to penetrate the peripheral portion thereof in the vertical direction and circumferentially arranged with an interval therebetween. The flange member 410 may have female screw grooves F41 formed therein and arranged to correspond to the respective through-holes H41 in the peripheral portion of the lower cover 430. The bolts M41 for coupling of the flange member 410 to the lower cover 430 may be screwed in the respective female screw grooves F41 in the flange member 410 through the respective through-holes H41 in the peripheral portion of the lower cover 430. A space between the flange member 410 and the lower cover 430 may be maintained in the airtight state by a sealing member S41. The sealing member S41 configured to maintain airtightness between the flange member 410 and the lower cover 430 may be interposed between the lower surface of the flange member 410 and the upper surface of the peripheral portion of the lower cover 430. The sealing members S41 interposed between the flange member 410 and the lower cover 430 may be arranged along the peripheral portion of the lower cover 430 in the circumferential direction. Each of the sealing members S41 interposed between the flange member 410 and the lower cover 430 may be formed to have a ring shape.

The upper surface of the central portion of the lower cover 430 having a ring structure may be coupled to the lower surface of the peripheral coupling portion 422 of the coupling member 420 by bolts M42. Referring to FIGS. 3, 4, 6 to 8, and the like, the lower cover 430 may have through-holes H42 formed to penetrate the central portion thereof in the vertical direction and circumferentially arranged with an interval therebetween. The peripheral coupling portion 422 of the coupling member 420 may have female screw grooves F42 formed therein and arranged to correspond to the respective through-holes H42 in the central portion of the lower cover 430. The bolts M42 for coupling of the coupling member 420 to the lower cover 430 may be screwed in the respective female screw grooves F42 in the peripheral coupling portion 422 of the coupling member 420 through the respective through-holes H42 in the central portion of the lower cover 430. A space between the coupling member 420 and the lower cover 430 may be maintained in the airtight state by a sealing member S42. The sealing member S42 configured to maintain airtightness between the coupling member 420 and the lower cover 430 may be interposed between the lower surface of the peripheral coupling portion 422 of the coupling member 420 and the upper surface of the central portion of the lower cover 430. The sealing members S42 interposed between the coupling member 420 and the lower cover 430 may be circumferentially arranged along the central portion of the lower cover 430. Each of the sealing members S42 interposed between the coupling member 420 and the lower cover 430 may be formed to have a ring shape.

Meanwhile, as shown in FIG. 1, the internal door 150 may be configured to contact, when the internal lower end opening 106 is closed, the coupling member 420 (or the lower cover 430) of the lower cover module 400 without contacting the lower end of the internal chamber 100. As a result, when the internal lower end opening 106 is closed, the internal door 150 does not directly contact the lower end of the internal chamber 100, thereby preventing significant impact caused by direct contact between the internal door 150 and the internal chamber 100 from being applied to the brittle internal chamber 100. Although not shown in the drawings, when the internal lower end opening 106 is closed, a sealing member such as an O-ring for maintaining airtightness may be interposed between the internal door 150 and the coupling member 420. The elastic member 530 may absorb impact that may be applied to the internal chamber 100 during the closing process of the internal lower end opening 106.

According to the shielding element CE configured as described above, in the high-pressure annealing device according to the embodiment of the present disclosure, since the lower portion of the external space 205 provided between the internal chamber 100 and the external chamber 200 is sealed, it is possible to prevent particles that may be generated from the heating module 300 from being discharged from the external space 205 provided between the internal chamber 100 and the external chamber 200. In this manner, it is possible to actively suppress occurrence of a substrate contamination problem caused by particles and deterioration in yield due to the substrate contamination problem. Additionally, in the high-pressure annealing device according to the embodiment of the present disclosure, the shielding element CE supports the brittle internal chamber 100 in a contact manner in a state of being coupled to the external chamber 200 having relatively excellent strength, thereby stably fixing the position of the brittle internal chamber 100 without a separate support structure.

As is apparent from the above description, according to the embodiment of the present disclosure, since a shielding element configured to seal a lower portion of an external space is provided in a high-pressure annealing device, it is possible not only to prevent particles that may be generated from a heating module from being discharged from the external space provided between an internal chamber and an external chamber, but also to actively suppress occurrence of a substrate contamination problem caused by particles and deterioration in yield due to the substrate contamination problem.

The shielding element is configured to support the internal chamber in a contact manner in a state of being coupled to the external chamber, thereby having an effect of stably fixing the position of the brittle internal chamber without a separate support structure.

The effects of the present disclosure are not limited to the above-mentioned effects, and other effects not mentioned herein will be clearly understood by those skilled in the art to which the present disclosure pertains from the specification and the attached drawings.

Although the present disclosure have been described above, the present disclosure is not limited to the disclosed embodiments and the accompanying drawings, and those skilled in the art will appreciate that various modifications, additions, and substitutions are possible, without departing from the scope and spirit of the disclosure. Furthermore, the technical ideas described in the embodiments of the present disclosure may be implemented independently or in combination of two or more.

What is claimed is:

1. A high-pressure annealing device comprising:
an internal chamber configured to provide an internal space to perform heat treatment on a substrate, the internal chamber having an open lower portion;
an external chamber configured to accommodate the internal chamber therein, the external chamber having an open lower portion;
a heating module configured to heat the internal chamber, the heating module being disposed in an external space provided between the internal chamber and the external chamber;
a chamber door configured to open or close, through an upward-and-downward movement operation, at least one of the open lower portion of the internal chamber and the open lower portion of the external chamber;
a substrate holder provided on the chamber door, the substrate holder entering and exiting the internal space in response to the upward-and-downward movement operation of the chamber door; and
a shielding element located between the internal chamber and the external chamber and configured to seal a lower portion of the external space.

2. The high-pressure annealing device as claimed in claim 1, wherein a first gas is supplied to the internal space at a first pressure, and
wherein a second gas is supplied to the external space at a second pressure predetermined in relation to the first pressure.

3. The high-pressure annealing device as claimed in claim 1, wherein the internal chamber is formed of quartz, and
wherein the shielding element is coupled to a lower end portion of the external chamber and is configured to support a lower end portion of the internal chamber in a contact manner.

4. The high-pressure annealing device as claimed in claim 1, wherein the shielding element comprises an upper cover and a lower cover disposed below the upper cover, and
wherein the shielding element is configured to double-seal the lower portion of the external space using the upper cover and the lower cover.

5. The high-pressure annealing device as claimed in claim 1, wherein the shielding element comprises:
an upper cover module having a ring-shaped structure, the upper cover module being configured to seal the lower portion of the external space in a state in which a peripheral portion of the upper cover module is coupled to a lower end portion of the external chamber and a central portion thereof supports a lower end portion of the internal chamber;
a spacer having a ring-shaped structure, the spacer being configured to support the upper cover module from below; and
a lower cover module having a ring-shaped structure, the lower cover module being disposed below the upper cover module and being configured to seal the lower portion of the external space in a state in which a peripheral portion of the lower cover module is coupled to the lower end portion of the external chamber and a central portion thereof supports the spacer.

6. The high-pressure annealing device as claimed in claim 5, wherein the internal chamber has a flange provided at the lower end portion of the internal chamber, and
wherein the upper cover module supports the flange of the internal chamber.

7. The high-pressure annealing device as claimed in claim 6, wherein the upper cover module comprises:
an upper cover comprising a peripheral ring portion coupled to the lower end portion of the external chamber and a central ring portion formed to have a supporting upper surface adapted to support the flange of the internal chamber from below; and
a pressing ring coupled to the upper cover from above the upper cover, the pressing ring having a pressing lower surface adapted to press the flange.

8. The high-pressure annealing device as claimed in claim 7, wherein the heating module has a flange provided at a lower end portion of the heating module, the flange of the heating module being coupled to the lower end portion of the external chamber, and
wherein the peripheral ring portion of the upper cover is coupled to the lower end portion of the heating module such that the upper cover is coupled to the lower end portion of the external chamber with the heating module interposed therebetween.

9. The high-pressure annealing device as claimed in claim 7, wherein the heating module has a ring jaw disposed above the pressing ring,
wherein the upper cover module further comprises an elastic member, and
wherein the elastic member is interposed between the ring jaw and the pressing ring in a vertically compressed state.

10. The high-pressure annealing device as claimed in claim 7, wherein the upper cover module further comprises a buffer pad interposed between the pressing lower surface of the pressing ring and the flange of the internal chamber.

11. The high-pressure annealing device as claimed in claim 2, wherein the internal chamber is formed of quartz, and
wherein the shielding element is coupled to a lower end portion of the external chamber and is configured to support a lower end portion of the internal chamber in a contact manner.

12. The high-pressure annealing device as claimed in claim 2, wherein the shielding element comprises an upper cover and a lower cover disposed below the upper cover, and
wherein the shielding element is configured to double-seal the lower portion of the external space using the upper cover and the lower cover.

13. The high-pressure annealing device as claimed in claim 2, wherein the shielding element comprises:
an upper cover module having a ring-shaped structure, the upper cover module being configured to seal the lower portion of the external space in a state in which a peripheral portion of the upper cover module is coupled to a lower end portion of the external chamber and a central portion thereof supports a lower end portion of the internal chamber;
a spacer having a ring-shaped structure, the spacer being configured to support the upper cover module from below; and
a lower cover module having a ring-shaped structure, the lower cover module being disposed below the upper cover module and being configured to seal the lower portion of the external space in a state in which a peripheral portion of the lower cover module is coupled to the lower end portion of the external chamber and a central portion thereof supports the spacer.

14. The high-pressure annealing device as claimed in claim 13, wherein the internal chamber has a flange provided at the lower end portion of the internal chamber, and
wherein the upper cover module supports the flange of the internal chamber.

15. The high-pressure annealing device as claimed in claim 14, wherein the upper cover module comprises:
an upper cover comprising a peripheral ring portion coupled to the lower end portion of the external chamber and a central ring portion formed to have a supporting upper surface adapted to support the flange of the internal chamber from below; and
a pressing ring coupled to the upper cover from above the upper cover, the pressing ring having a pressing lower surface adapted to press the flange.

16. The high-pressure annealing device as claimed in claim 15, wherein the heating module has a flange provided at a lower end portion of the heating module, the flange of the heating module being coupled to the lower end portion of the external chamber, and
wherein the peripheral ring portion of the upper cover is coupled to the lower end portion of the heating module such that the upper cover is coupled to the lower end portion of the external chamber with the heating module interposed therebetween.

17. The high-pressure annealing device as claimed in claim 15, wherein the heating module has a ring jaw disposed above the pressing ring,
wherein the upper cover module further comprises an elastic member, and
wherein the elastic member is interposed between the ring jaw and the pressing ring in a vertically compressed state.

18. The high-pressure annealing device as claimed in claim 15, wherein the upper cover module further comprises a buffer pad interposed between the pressing lower surface of the pressing ring and the flange of the internal chamber.
